(19) United States
(12) Patent Application Publication
(10) Pub. No.: US 2025/0234522 A1
(43) Pub. Date: Jul. 17, 2025

(54) BITLINE SURFACE TREATMENT AND ENCAPSULATION IN DYNAMIC RANDOM-ACCESS MEMORY (DRAM) DEVICES

(71) Applicant: Applied Materials, Inc., Santa Clara, CA (US)

(72) Inventors: Jongbeom SEO, Sunnyvale, CA (US); Zhijun CHEN, San Jose, CA (US); Fredrick FISHBURN, Aptos, CA (US); Raghuveer Satya MAKALA, Santa Clara, CA (US)

(21) Appl. No.: 18/984,928

(22) Filed: Dec. 17, 2024

Related U.S. Application Data
(60) Provisional application No. 63/621,174, filed on Jan. 16, 2024.

(51) Int. Cl. H10B 12/00

(52) U.S. Cl. CPC H10B 12/482; H10B 12/02

(57) ABSTRACT

A memory cell array includes a bitline encapsulated in a blocking layer within a spacer layer, the bitline extending in a first direction, and a plurality of memory cells aligned in the first direction, each of the plurality of memory cells including a cell transistor having a source electrically connected to the bitline, a drain, a word line, and a channel electrically connected to the source and the drain, and a cell capacitor having a top electrode that is electrically connected to the drain.

### CROSS-REFERENCE TO RELATED APPLICATIONS

This application claims priority to U.S. Provisional Application Ser. No. 63/621,174 filed Jan. 16, 2024, which is herein incorporated by reference in its entirety.

### BACKGROUND

### Field

Embodiments described herein generally relate to semiconductor device fabrication, and more particularly, to surface treatment of encapsulation of bitlines in dynamic random-access memory devices.

### Description of the Related Art

Dynamic random-access memory (DRAM) devices pose challenges in manufacturability due to their designs and small sizes. As the number of vertical stacks of memory cells in DRAM devices increases (e.g., as chip densities increase), the height of each of the vertical stacks needs to be reduced.

In DRAM devices, a bitline with low resistance is pursued to maximize the sense signal margin and thus molybdenum (Mo) has been used to form bitlines in DRAM devices due to its intrinsic low resistivity property. However, molybdenum (Mo) may be easily oxidized or nitridized during a DRAM device integration process and thus the low resistivity property may be degraded.

Therefore, there is a need for recovering molybdenum (Mo) bitlines from patterning damage and protecting molybdenum (Mo) bitlines from further oxidation or nitridization until the end of a DRAM device integration process.

### SUMMARY

Embodiments of the present disclosure provide a memory cell array. The memory cell array includes a bitline encapsulated in a blocking layer within a spacer layer, the bitline extending in a first direction, and a plurality of memory cells aligned in the first direction, each of the plurality of memory cells including a cell transistor having a source electrically connected to the bitline, a drain, a word line, and a channel electrically connected to the source and the drain, and a cell capacitor having a top electrode that is electrically connected to the drain.

Embodiments of the present disclosure also provide a method of forming a memory cell array in a semiconductor memory device. The method includes performing a bitline patterning process to pattern a bitline metal and form bitlines extending in a first direction, performing a post-treatment process to remove oxide or nitrogen residues from inner surfaces of slits between adjacent bitlines, performing a blocking layer deposition process to deposit a blocking layer on the post-treated inner surfaces of the slits, performing a bitline spacer deposition process to deposit a spacer layer on the blocking layer, and performing a slit fill process to fill the slits with dielectric material.

Embodiments of the present disclosure further provide a multi-chamber cluster tool. The multi-chamber cluster tool includes a first processing chamber, a second processing chamber, a third processing chamber, a fourth processing chamber, and a controller configured to cause the multi-chamber cluster tool to perform, in the first processing chamber, a bitline patterning process to pattern a bitline metal and form bitlines extending in a first direction, perform, in the second processing chamber, a post-treatment process to remove oxide or nitrogen residues from inner surfaces of the slits, perform, in the third processing chamber, a blocking layer deposition process to deposit a blocking layer on the post-treated inner surfaces of the slits, and perform, in the fourth processing chamber, a bitline spacer deposition process to deposit a spacer layer on the blocking layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2A is a schematic view of a portion of a memory cell array of dynamic random access memory (DRAM) cells according to one embodiment.

FIG. 2B is a schematic diagram of a DRAM cell.

FIG. 3 depicts a process flow diagram of a method of forming cell transistors in a semiconductor structure according to one embodiment.

FIGS. 4A, 4B, 4C, and 4D are cross-sectional views of a portion of a semiconductor structure corresponding to various states of the method of FIG. 3.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods and systems for a DRAM device integration process, in which bitlines are post-treated to remove oxide or nitride residues from their exposed surfaces and encapsulated to protect the exposed surfaces from further oxidation or nitridation. The post-treatment includes a hydrogen-based treatment process. The encapsulation includes depositing a carbon-based thin blocking layer on the surfaces of the bitlines. Bitlines formed according to the embodiments described herein can have low metal resistance that can contribute a low bitiline capacitance, and thus lead to a better sensing signal performance in a DRAM device.

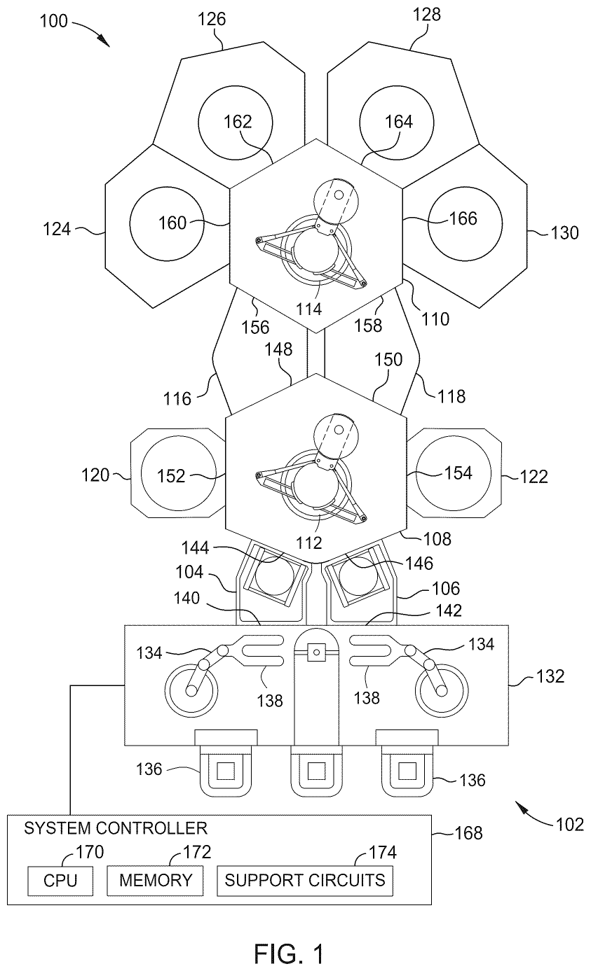

FIG. 1 is a schematic top view of a multi-chamber cluster tool 100, according to one or more embodiments of the present disclosure. The multi-chamber cluster tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber cluster tool 100 can be processed in and transferred between the various chambers without exposing the substrates to an ambient environment exterior to the multi-chamber cluster tool 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber cluster tool 100. Accordingly, the multi-chamber cluster tool 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

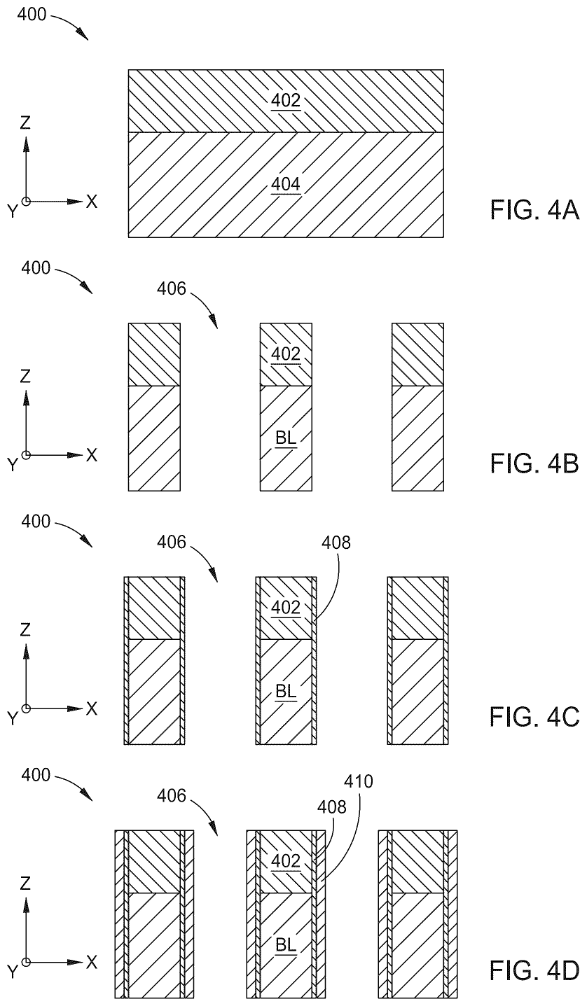

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be an Aktiv™ Pre-clean (APC) chamber, a Pre-clean XT (MCxT-2) chamber, or a SiCoNi™ Pre-clean chamber, available from Applied Materials of Santa Clara, Calif. The processing chamber 124, 126, 128, or 130 may be a Centura™ Epi chamber, a Volta™ CVD/ALD chamber, an Encore™ PVD chamber, a selective tungsten deposition chamber, an ionized metal plasma physical vapor deposition (IMP PVD) chamber, a rapid thermal process (RTP) chamber, or a plasma etch (PE) chamber, available from Applied Materials of Santa Clara, Calif. A system controller 168 is coupled to the multi-chamber cluster tool 100 for controlling the multi-chamber cluster tool 100 or components thereof. For example, the system controller 168 may control the operation of the multi-chamber cluster tool 100 using a direct control of the chambers 104, 106, 108, 110, 116, 118, 120, 122, 124, 126, 128, 130 of the multi-chamber cluster tool 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the multi-chamber cluster tool 100. The system controller 168 is configured to cause the chambers 104, 106, 108, 110, 116, 118, 120, 122, 124, 126, 128, 130 of the multi-chamber cluster tool 100 to perform all of the operations described with respect to FIGS. 4 and 5.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

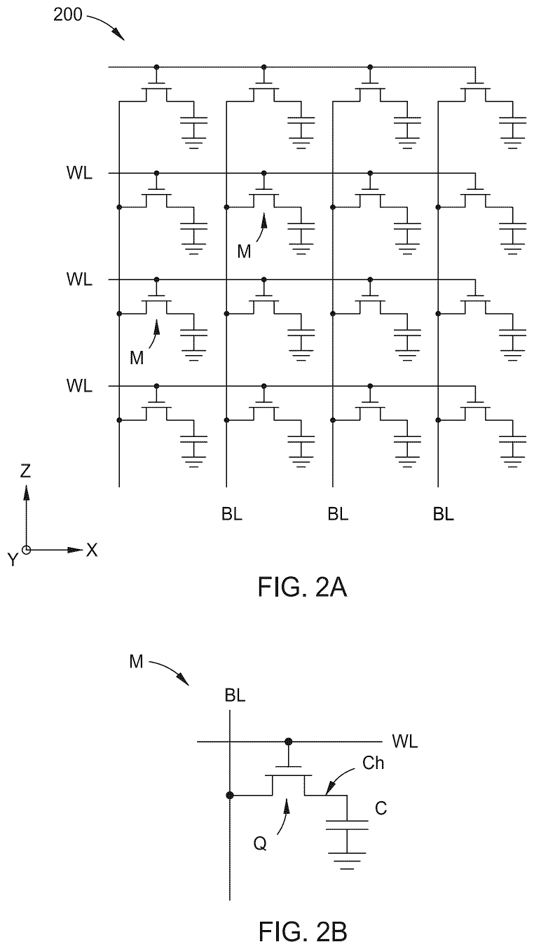

FIG. 2A is a schematic diagram of a portion of a two-dimensional (2D) memory cell array 200 of dynamic random access memory (DRAM) cells (also referred to as “memory cells”) M, according to one or more embodiments of the present disclosure.

As shown in FIG. 2B, a single memory cell M includes a cell transistor Q and a cell capacitor C. A memory cell M stores a datum bit by storing a packet of charge (i.e., a binary one) or no charge (i.e., a binary zero) on the cell capacitor C. A datum bit is input and output by a bitline BL that is connected to the source of the cell transistor Q, and input is controlled by a word line WL that is connected to the gate of the cell transistor Q. The drain of the cell transistor Q is connected to a top electrode of the cell capacitor C by a channel Ch that connects electrically connects the source and the train.

In the memory cell array 200, bitlines BL extend in the Z direction, and word lines WL extend in the X direction. Each of the bitlines BL is linked to the sources of cell transistors Q that are aligned in the Z direction. Each of the word lines WL is linked to the gates of the cell transistors that are aligned in the X direction.

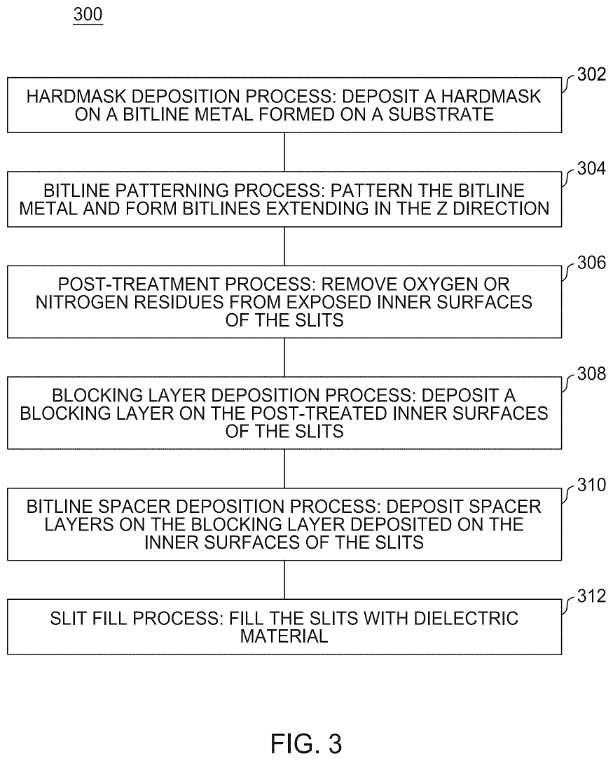

FIG. 3 depicts a process flow diagram of a method 300 of a device integration process forming a portion of a semiconductor structure 400 that may form a memory cell array, such as a portion of the memory cell array 200. FIGS. 4A, 4B, 4C, and 4D are cross-sectional views of a portion of the semiconductor structure 400 corresponding to various states of the method 300. It should be understood that FIGS. 4A, 4B, 4C, and 4D illustrate only partial schematic views of the semiconductor structure 400, and the semiconductor structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein.

The method 300 begins with block 302, in which a hardmask deposition process is performed to deposit a hardmask 402 on a bitline metal 404 formed on a substrate (not shown), as shown in FIG. 4A. The bitline metal 404 may be molybdenum (Mo). The hardmask deposition process may include any conventional deposition process, such as a chemical vapor deposition (CVD) process, a physical vapor deposition (PVD) process, an atomic layer deposition (ALD) process, or a spin-on process performed in a processing chamber, such as the processing chamber 126, 128, or 130 shown in FIG. 1. The hardmask 402 may be subsequently patterned by a conventional photolithographic process using a patterned photoresist layer (not shown) covering the hardmask 402.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire. The substrate may include a field-effect transistor (FET) module, which may form a cell transistor Q shown in FIGS. 2A and 2B, and a capacitor module, which may form a cell transistor C shown in FIGS. 2A and 2B.

The hardmask 402 may be formed of silicon nitride (Si₃N₄) or silicon oxynitride (SiON).

In block 304, a bitline patterning process is performed to pattern the bitline metal 404 and form bitlines BL extending in the Z direction, which may form bitlines BL shown in FIGS. 2A and 2B, as shown in FIG. 4B. The bitline patterning process may include any appropriate lithography and etch processes, such as photolithography. The etch process may include any appropriate wet etching process, performed in a processing chamber, such as the processing chamber 120 shown in FIG. 1.

In the 2-D memory cell array, slits 406 between adjacent bitlines BL may each have a width in the X direction of between about 20 nm and about 40 nm.

Subsequently, the hardmask 402 may be removed by any appropriate etching process.

In block 306, a post-treatment process is performed to remove oxygen or nitrogen residues from exposed inner surfaces of the slits 406. The post-treatment process may include a plasma treatment process, performed in a pre-clean chamber, such as the processing chamber 122 shown in FIG. 1. In the plasma treatment process, the inner surfaces of the slits 406 are exposed to a plasma formed from a process gas including hydrogen (H₂), a mixture of hydrogen (H₂) and nitrogen (N₂), a mixture of hydrogen (H₂) and methane (CH₄), a mixture of hydrogen (H₂) and noble gas (e.g., helium (He), argon (Ar)), or any combination thereof. The plasma treatment process may be a radical-based pre-cleaning technique using a remote plasma assisted process in a processing chamber, such as Aktiv™ Pre-clean (APC) chamber available from Applied Materials of Santa Clara, Calif. The plasma treatment process may be a capacitively coupled plasma (CCP) process performed in a processing chamber, such as Pre-clean XT (MCxT-2) chamber available from Applied Materials of Santa Clara, Calif. The plasma treatment process may be performed at a temperature of between about 300° C. and about 600° C. for a duration of between about 10 seconds and about 600 seconds.

In block 308, a blocking layer deposition process is performed to deposit a blocking layer 408 on the post-treated inner surfaces of the slits 406, as shown in FIG. 4C. The blocking layer deposition process may be a soaking process performed in a thermal processing chamber, a plasma chamber, a radical chamber, or an ALD chamber, such as the processing chamber 124, 126, 128, or 130 shown in FIG. 1. The post-treatment process in block 306 and the blocking layer deposition process in block 308 may be performed in a multi-chamber cluster tool, such as the multi-chamber cluster tool 100, shown in FIG. 1, without vacuum break.

The blocking layer 408 may be formed of a self-assembled monolayer (SAM) of organic molecules, such as methane (CH₄), or a thin layer of dielectric material, such as silicon dioxide (SiO₂), silicon nitride (Si₃N₄), silicon carbonitride (SiCN), silicon oxycarbide (SiOC), or silicon oxynitride (SiON), or a combination thereof, having a thickness in the X direction of less than about 20 Å. In the soaking process, the semiconductor structure 400 is soaked in a gas precursor including an unsaturated hydrocarbon, at a temperature of less than about 450° C. and a pressure of less than about 80 Torr for a duration of greater than about 10 seconds, with a flow rate of the precursor of between 50 sccm and about 600 sccm. In some embodiments, a liquid precursor is used in the soaking process. In the soaking process, organic molecules in the precursor are absorbed on a metal surface, such as the exposed surface of the bitlines BL. The blocking layer 408 may suppress interaction of a subsequent material deposition thereon with the bitlines BL, and thus protect the bitlines BL from oxidation or nitridation until the end of the device integration process.

In block 310, a bitline spacer deposition process is performed to deposit spacer layers 410 on the blocking layer 408 deposited on the inner surfaces of the slits 406, as shown in FIG. 4D. The bitline spacer deposition process may include any appropriate deposition process, such as chemical vapor deposition (CVD), physical vapor deposition (PVD), or the like performed in a processing chamber, such as the processing chamber 126, 128, or 130 shown in FIG. 1.

The spacer layers 410 may be formed of dielectric material, such as silicon nitride (Si₃N₄), silicon dioxide (SiO₂), silicon oxynitride (SiON), silicon carbonitride (SiCN), or silicon oxycarbide (SiOC) and have a thickness in the X direction of between about 2 nm and about 15 nm.

In block 312, a slit fill process is performed to fill the slits 406 with dielectric material. The slit fill process may include deposition process, such as chemical vapor deposition (CVD), physical vapor deposition (PVD), or atomic layer deposition (ALD) process.

The embodiments described herein provide methods and systems for a DRAM device integration process, in which bitlines are post-treated to remove oxide or nitride residues from their exposed surfaces and encapsulated to protect the exposed surfaces from further oxidation or nitridation process. The post-treatment includes a hydrogen-based treatment process. The encapsulation includes depositing a carbon-based thin blocking layer on the surfaces of the bitlines. Bitlines formed according to the embodiments described herein can have low metal resistance that can contribute a low bitiline capacitance, and thus lead to a better sensing signal performance in a DRAM device.

While the foregoing is directed to embodiments of the present disclosure, other and further embodiments of the disclosure may be devised without departing from the basic scope thereof, and the scope thereof is determined by the claims that follow.

1. A memory cell array, comprising:
a bitline encapsulated in a blocking layer within a spacer layer, the bitline extending in a first direction; and
a plurality of memory cells aligned in the first direction, each of the plurality of memory cells comprising:
a cell transistor having:
a source electrically connected to the bitline;
a drain;
a word line; and
a channel electrically connected to the source and the drain; and
a cell capacitor having a top electrode that is electrically connected to the drain.

2. The memory cell array of claim 1, wherein the bitline comprises molybdenum (Mo).

3. The memory cell array of claim 1, wherein the blocking layer comprises a self-assembled monolayer (SAM) of organic molecules.

4. The memory cell array of claim 1, wherein the blocking layer has a thickness of less than 20 Å.

5. The memory cell array of claim 1, wherein the spacer layer comprises silicon nitride (Si₃N₄), silicon dioxide (SiO₂), silicon oxynitride (SiON), silicon carbonitride (SiCN), or silicon oxycarbide (SiOC).

6. The memory cell array of claim 1, wherein the spacer layer has a thickness of between 2 nm and 15 nm.

7. A method of forming a memory cell array in a semiconductor memory device, comprising:
performing a bitline patterning process to pattern a bitline metal and form bitlines extending in a first direction;
performing a post-treatment process to remove oxide or nitrogen residues from inner surfaces of slits between adjacent bitlines;
performing a blocking layer deposition process to deposit a blocking layer on the post-treated inner surfaces of the slits;
performing a bitline spacer deposition process to deposit a spacer layer on the blocking layer; and
performing a slit fill process to fill the slits with dielectric material.

8. The method of claim 7, wherein the bitline metal comprises molybdenum (Mo).

9. The method of claim 7, wherein the post-treatment process comprises exposing the inner surfaces of the slits to a plasma formed from a process gas including hydrogen (H₂), a mixture of hydrogen (H₂) and nitrogen (N₂), a mixture of hydrogen (H₂) and methane (CH₄), a mixture of hydrogen (H₂) and noble gas, or any combination thereof.

10. The method of claim 7, wherein the blocking layer deposition process comprises soaking the post-treated inner surfaces of the slits in a gas precursor including an unsaturated hydrocarbon.

11. The method of claim 10, wherein the blocking layer comprises a self-assembled monolayer (SAM) of organic molecules.

12. The method of claim 11, wherein the blocking layer has a thickness of less than 20 Å.

13. The method of claim 7, wherein the spacer layer comprises silicon nitride (Si₃N₄), silicon dioxide (SiO₂), silicon oxynitride (SiON), silicon carbonitride (SiCN), or silicon oxycarbide (SiOC).

14. A multi-chamber cluster tool comprising:
a first processing chamber;
a second processing chamber;
a third processing chamber;
a fourth processing chamber; and
a controller configured to cause the multi-chamber cluster tool to:
perform, in the first processing chamber, a bitline patterning process to pattern a bitline metal and form bitlines extending in a first direction;
perform, in the second processing chamber, a post-treatment process to remove oxide or nitrogen residues from inner surfaces of slits between adjacent bitlines;
perform, in the third processing chamber, a blocking layer deposition process to deposit a blocking layer on the post-treated inner surfaces of the slits; and
perform, in the fourth processing chamber, a bitline spacer deposition process to deposit a spacer layer on the blocking layer.

15. The multi-chamber cluster tool of claim 14, wherein the post-treatment process and the blocking layer deposition process are performed without vacuum break.

16. The multi-chamber cluster tool of claim 14, further comprising:
a fifth processing chamber, wherein the controller is further configured to cause the multi-chamber cluster tool to:
perform, in the fifth processing chamber, a slit fill process to fill the slits with dielectric material.

17. The multi-chamber cluster tool of claim 14, wherein the bitline metal comprises molybdenum (Mo).

18. The multi-chamber cluster tool of claim 14, wherein the post-treatment process comprises exposing the inner surfaces of the slits to a plasma formed from a process gas including hydrogen (H₂), a mixture of hydrogen (H₂) and nitrogen (N₂), a mixture of hydrogen (H₂) and methane (CH₄), a mixture of hydrogen (H₂) and noble gas, or any combination thereof.

19. The multi-chamber cluster tool of claim 14, wherein:
the blocking layer deposition process comprises soaking the post-treated inner surfaces of the slits in a gas precursor including an unsaturated hydrocarbon.

20. The multi-chamber cluster tool of claim 14, wherein:
the blocking layer comprises a self-assembled monolayer (SAM) of organic molecules having a thickness of less than 20 Å.
